(19) United States
(12) Patent Application Publication
(10) Pub. No.: US 2022/0076985 A1
(43) Pub. Date: Mar. 10, 2022

(54) WAFER SUPPORT, WAFER PROCESSING DEVICE AND WAFER PROCESSING METHOD

(71) Applicant: CHANGXIN MEMORY TECHNOLOGIES, INC., Hefei City (CN)

(72) Inventor: JONG HYUNG CHO, Hefei City (CN)

(21) Appl. No.: 17/455,333

(22) Filed: Nov. 17, 2021

Related U.S. Application Data
(63) Continuation of application No. PCT/CN2021/077007, filed on Feb. 20, 2021.

(30) Foreign Application Priority Data
Feb. 29, 2020 (CN) 202010131734.9

(51) Int. Cl. H01L 21/687; C23C 16/458

(52) U.S. Cl. CPC H01L 21/6875; C23C 16/4583; H01L 21/68771

(57) ABSTRACT

Disclosed are a wafer support, a wafer processing device and a wafer processing method. The wafer support includes a cylinder, a sidewall of the cylinder including a first wall surface facing a wafer, a second wall surface facing away from the wafer and two third wall surfaces connected to the first wall surface and the second wall surface, the first wall surface being arranged opposite to the second wall surface, the two third wall surfaces being arranged opposite to each other, the two third wall surfaces being arranged at an angle, and a distance between the two third wall surfaces gradually decreasing in a direction close to the first wall surface; and one or more supporting blocks sequentially spaced apart on the first wall surface from top to bottom, the supporting block being configured to support the wafer.

### CROSS-REFERENCE TO RELATED APPLICATIONS

This application is a continuation application of International Patent Application No. PCT/CN2021/077007, filed on Feb. 20, 2021, which claims priority to Chinese Patent Application No. 202010131734.9, filed with the Chinese Patent Office on Feb. 29, 2020 and entitled “WAFER SUPPORT, WAFER PROCESSING DEVICE AND WAFER PROCESSING METHOD”. International Patent Application No. PCT/CN2021/077007 and Chinese Patent Application No. 202010131734.9 are incorporated herein by reference in their entireties.

### TECHNICAL FIELD

The present invention relates to a wafer support, a wafer processing device and a wafer processing method.

### BACKGROUND

In order to develop next-generation high-performance semiconductor products with a high added value, technologies are developing towards integrated design rules. A conventional wafer processing device includes a furnace body, a wafer support arranged in the furnace body and an air duct for introducing reaction gas into the furnace body. A wafer to be processed by reaction is placed on the wafer support, the air duct introduces the reaction gas into the furnace body to react with the wafer, and the gas after reaction is withdrawn from the furnace body by a suction mechanism, and so on. After a few hours or more than ten hours of reaction time, the reaction gas reacts and then is deposited on a surface of the wafer to form a film.

### SUMMARY

According to various embodiments, the present application provides a wafer support, including: a cylinder, a sidewall of the cylinder including a first wall surface facing a wafer, a second wall surface facing away from the wafer and two third wall surfaces connected to the first wall surface and the second wall surface, the first wall surface being arranged opposite to the second wall surface, the two third wall surfaces being arranged opposite to each other, the two third wall surfaces being arranged at an angle, and a distance between the two third wall surfaces gradually decreasing in a direction close to the first wall surface; and one or more supporting blocks sequentially spaced apart on the first wall surface from top to bottom, the supporting block being configured to support the wafer.

According to various embodiments, the present application further provides a wafer support, including: a cylinder that is an elliptic cylinder, a sidewall of the cylinder including a first wall surface facing a wafer and a second wall surface facing away from the wafer, the first wall surface being connected to the second wall surface, and the second wall surface being an elliptic cylindrical surface; and one or more supporting blocks sequentially spaced apart on the first wall surface from top to bottom, the supporting block being configured to support the wafer.

According to various embodiments, the present application further provides a wafer processing method, using the wafer processing device described above for wafer processing. Details of one or more embodiments of the present application are set forth in the following accompanying drawings and descriptions. Other features and advantages of the present application become obvious with reference to the specification, the accompanying drawings, and the claims.

### BRIEF DESCRIPTION OF DRAWINGS

In order to more clearly illustrate the technical solutions in embodiments of the present application or the conventional technology, the accompanying drawings used in the description of the embodiments or the conventional technology will be briefly introduced below. It is apparent that, the accompanying drawings in the following description are only some embodiments of the present application, and other drawings can be obtained by those of ordinary skill in the art from the provided drawings without creative efforts.

FIG. 1 is a schematic structural diagram of a wafer supported by a conventional wafer support;

FIG. 2 is a side-view structural diagram of a wafer mounted on a wafer support according to an embodiment of the present invention;

FIG. 3 is a schematic top-view structural diagram of the wafer support according to an embodiment of the present invention;

FIG. 4 is a schematic diagram of a state when the wafer mounted on the wafer support operates according to an embodiment of the present invention;

FIG. 5 is a schematic top-view structural diagram of a wafer support according to another embodiment of the present invention;

FIG. 6 is a schematic top-view structural diagram of a wafer support according to yet another embodiment of the present invention;

FIG. 7 is a schematic top-view structural diagram of a wafer support according to still another embodiment of the present invention;

FIG. 8 is a schematic structural diagram of a wafer support according to still another embodiment of the present invention;

FIG. 9 is a schematic top-view structural diagram of a wafer support according to a further embodiment of the present invention;

FIG. 10 is a schematic structural diagram of a wafer support according to a further embodiment of the present invention;

FIG. 11 is a schematic structural diagram of a wafer support according to a further embodiment of the present invention;

FIG. 12 is a schematic structural diagram of a wafer processing device according to an embodiment of the present invention; and

FIG. 13 is a schematic structural diagram of a wafer supported by a wafer support according to an embodiment of the present invention.

### REFERENCE NUMERALS

10: wafer support; 11: cylinder; 111: first wall surface; 112: second wall surface; 113: third wall surface; 12: supporting block; 13: ventilation hole; 20: wafer; 30: reaction furnace body; 40: air duct; 50: suction mechanism; 60: rotary table; 70: wafer support; 71: cylinder; 72: supporting block.

### DESCRIPTION OF EMBODIMENTS

A thickness of a film corresponding to a surface part of a support on a wafer is less than thicknesses of films of other parts of the wafer. Low uniformity of the thicknesses of the films on the surface of the wafer leads to the low quality of wafer products.

In order to make the above objectives, features and advantages of the present invention more comprehensible, specific implementations of the present invention are described in detail below with reference to the accompanying drawings. Many specific details are described below for full understanding of the present invention. However, the present invention may be implemented in other manners different from those described herein. It may be appreciated by those of ordinary person skilled in the art that similar improvement may be made without departing from the idea of the present invention. The present invention is thus not limited by specific embodiments disclosed below.

In the description of the present invention, it should be understood that, the terms “first” and “second” are used for descriptive purposes only, which cannot be construed as indicating or implying a relative importance, or implicitly specifying the number of the indicated technical features. Thus, the features defined with “first” and “second” may explicitly or implicitly include one or more features. In the description of the present invention, “a plurality of” means at least two, such as two or three, unless specifically stated otherwise.

In the description of the present invention, it should be understood that, when an element is considered as “connected to” another element, the element may be directly connected to the another element or an intermediate element may co-exist. Conversely, no intermediate element exists when an element is referred to as “directly” connected to another element.

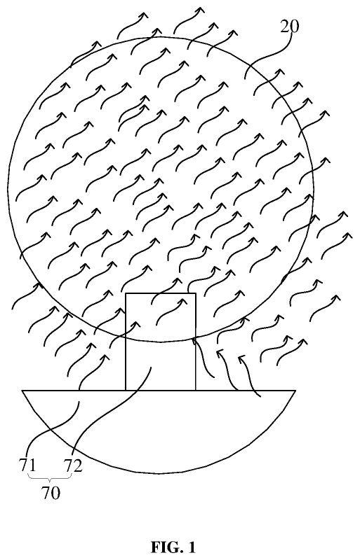

Referring to FIG. 1, generally, a conventional wafer processing device includes one or more wafer supports 70. The one or more wafer supports 70 are spaced apart around a wafer 20. The wafer 20 is placed synchronously on the one or more wafer supports 70 and is supported synchronously by the one or more wafer supports 70. The supporting effect is relatively stable. Specifically, the conventional wafer support 70 includes a cylinder 71 with a semicircular or nearly semicircular section and one or more supporting blocks 72 sequentially arranged from top to bottom on a flat side surface of the cylinder 71. The wafer 20 to be processed is placed on the supporting blocks 72. An air duct is arranged on a back surface of the cylinder 71, and a nozzle of the air duct faces an arc-shaped side surface of the cylinder 71. When the nozzle of the air duct exhausts air outwards, reaction gas is blown to the corresponding wafer 20 to be deposited on a surface of the wafer 20 to form a film. In order to ensure structural strength of the wafer support 70 to stably support a plurality of wafers 20, the cylinder 71 has a height of generally 1 m to 2 m, and the cylinder 71 is wider, with a width of generally more than 2 cm. However, in the process of blowing the reaction gas of the air duct to the wafer 20 of the wafer support 70, on the one hand, the cylinder 71 blocks the reaction gas; as a result, part of the reaction gas cannot flow directly to a surface part of the wafer 20 corresponding to the supporting block 72, so that the amount of gas on the surface part of the wafer 20 corresponding to the supporting blocks 72 decreases, and then the thickness of the film formed by deposition on the surface part of the wafer 20 corresponding to the supporting blocks 72 decreases. On the other hand, the cylinder 71 is wider, and in the process of withdrawing the gas after reaction corresponding to the wafer 20 from a furnace body through a suction mechanism, the cylinder 71 also plays a blocking role; as a result, the reaction gas resides in a region of the wafer support 70 to react and produce by-product particles attached to surfaces of the cylinder 71 and the supporting blocks 72, and the by-product particles are not easy to be withdrawn from the furnace body by the suction mechanism, thereby affecting the product quality of the wafer 20.

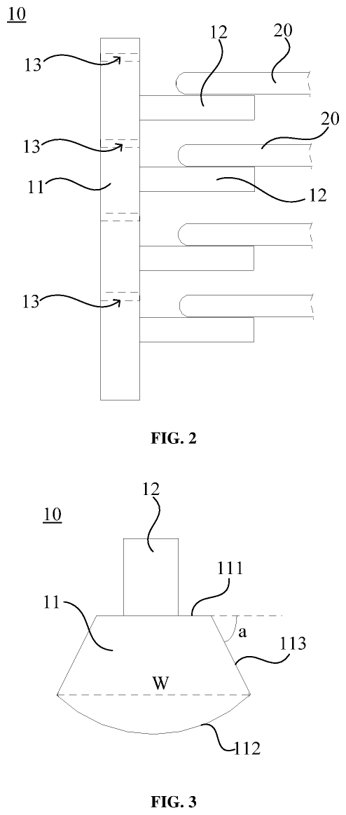

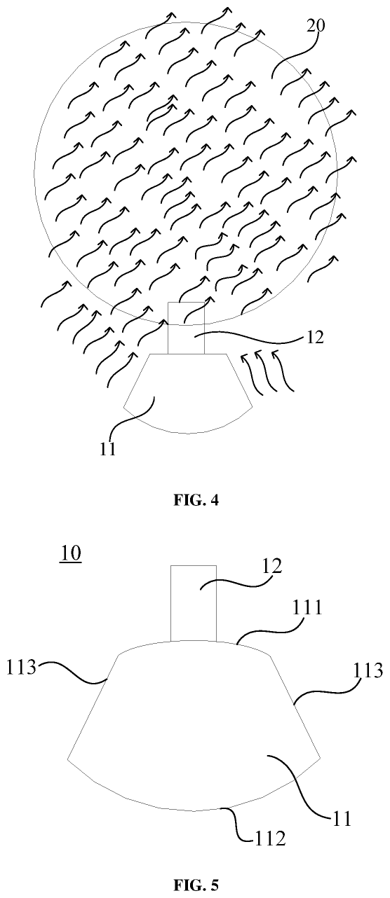

In one embodiment, referring to FIG. 2 to FIG. 4 and FIG. 12, a wafer support 10 includes a cylinder 11 and supporting blocks 12. A sidewall of the cylinder 11 includes a first wall surface 111 facing a wafer 20, a second wall surface 112 facing away from the wafer 20 and two third wall surfaces 113 connected to the first wall surface 111 and the second wall surface 112. The first wall surface 111 is arranged opposite to the second wall surface 112. The two third wall surfaces 113 are arranged opposite to each other, the two third wall surfaces 113 are arranged at an angle, and a distance between the two third wall surfaces 113 gradually decreases in a direction close to the first wall surface 111. One or more supporting blocks 12 are provided. The one or more supporting blocks 12 are sequentially spaced apart on the first wall surface 111 from top to bottom. The supporting block 12 is configured to support the wafer 20.

In the wafer support 10, the sidewall of the cylinder 11 includes the first wall surface 111, the second wall surface 112 and the two third wall surfaces 113, the two third wall surfaces 113 are arranged at an angle, and the distance between the two third wall surfaces 113 gradually decreases in the direction close to the first wall surface 111. That is, a cross section of the cylinder 11 is or is approximate to a fan-shaped surface, and the sidewall of the cylinder 11 can avoid preventing the contact of the reaction gas discharged from a nozzle of an air duct 40 with the wafer 20 as much as possible. In this way, the reaction gas discharged from the nozzle of the air duct 40 can flow uniformly over the entire surface of the wafer 20, the amount of gas on a surface part of the wafer 20 corresponding to the supporting blocks 12 is basically the same as the amount of gas on other parts of the wafer 20, and then the thickness of a film formed by deposition on the surface part of the wafer 20 corresponding to the supporting blocks 12 is basically the same as that of the film on other parts of the wafer 20. That is, the uniformity of deposition thicknesses of edge parts of the wafer 20 can be improved and the product quality of the wafer 20 can be improved. In addition, the width of the cylinder 11 is relatively decreased, and in the process of withdrawing the gas after reaction corresponding to the wafer 20 from the furnace body through a suction mechanism 50, the blocking effect of the cylinder 11 is also weakened, and the reaction gas is timely withdrawn from the reaction furnace body 30, so as to avoid as much as possible residence of the reaction gas in a region of the wafer support 10 which may react and produce by-product particles. Moreover, the by-product particles are also easy to be withdrawn from the reaction furnace body 30 by the suction mechanism 50.

Further, referring to FIG. 2 to FIG. 4, a distance between the sides of the two third wall surfaces 113 close to the second wall surface 112 is W, where W is not greater than 1 cm. In this way, the width of the cylinder 11 is relatively reduced; in other words, the blocking effect on the reaction gas is reduced, which is conducive to the flow of the reaction gas above the surface of the wafer 20.

In one embodiment, referring to FIG. 2 to FIG. 4, the first wall surface 111 is a plane, and the third wall surface 113 is also a plane, inclined relative to the first wall surface 111. An angle between the third wall surface 113 and the first wall surface 111 is a, where a is 20° to 50°. In this way, on the one hand, the cylinder 11 in the angle range has little blocking effect on the reaction gas; on the other hand, the structural strength of the cylinder 11 can be ensured, so that it is not easy to break and can support the plurality of wafers 20.

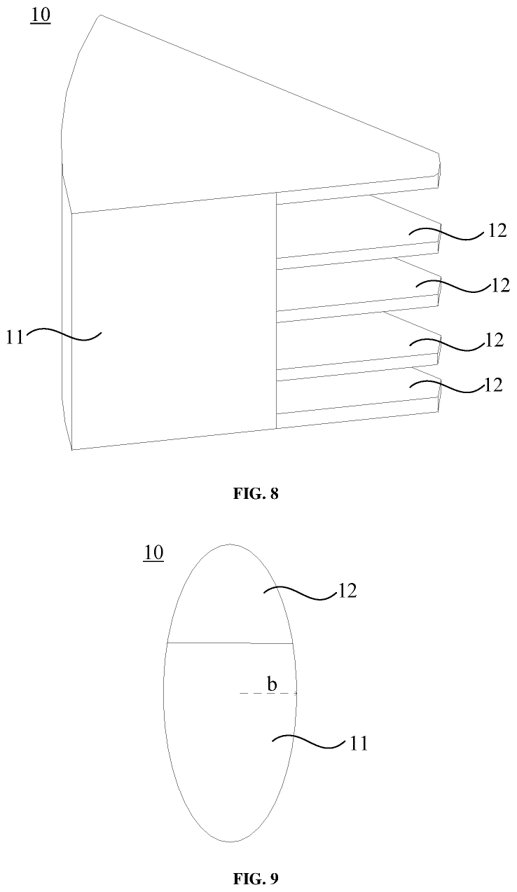

Further, referring to FIG. 2 to FIG. 4, FIG. 7 and FIG. 8, a is 30° to 40°. This has little blocking effect on the reaction gas while better ensuring the structural strength of the cylinder 11. Preferably, a is specifically, for example, 33°, 34°, 35°, 36°, 37°, 38° or 39°.

In addition, specifically, the second wall surface 112 is an arc-shaped surface. In this way, the arc-shaped second wall surface 112 guides the reaction gas discharged from the nozzle of the air duct 40 outwards, which facilitates the reaction gas to flow above the wafer 20 and react with the wafer 20.

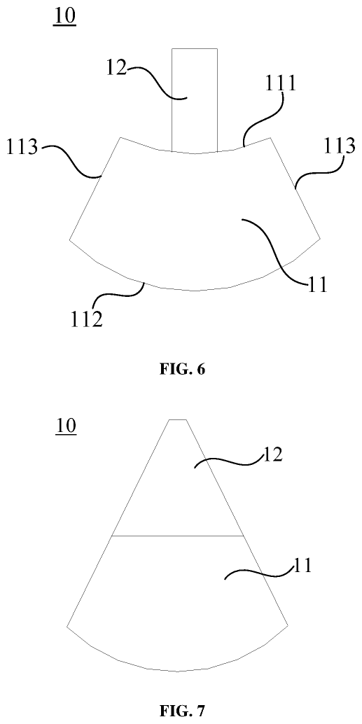

In another embodiment, referring to FIG. 5 and FIG. 6, the first wall surface 111 is an arc-shaped surface, the second wall surface 112 is an arc-shaped surface, and the third wall surface 113 is a plane. An opening of the arc-shaped surface of the first wall surface 111 may face the second wall surface 112 or may face away from the second wall surface 112. This can also reduce the blocking effect on the reaction gas and realize the better flow of the reaction gas above the wafer 20.

In one embodiment, referring to FIG. 2, the cylinder 11 is further provided with one or more ventilation holes 13, the ventilation holes 13 are arranged corresponding to the supporting blocks 12, and the ventilation hole 13 extends from the first wall surface 111 to the second wall surface 112. In this way, on the one hand, the reaction gas discharged from the nozzle of the air duct 40 can flow above the wafer 20 through the ventilation hole 13, so that the amount of gas on a surface part of the wafer 20 corresponding to the supporting block 12 is basically the same as that on other parts of the wafer 20, and then the thickness of the film formed by deposition on the surface part of the wafer 20 corresponding to the supporting block 12 is basically the same as that of the film on other parts of the wafer 20; that is, the uniformity of deposition thicknesses of edge parts of the wafer 20 can be improved, so as to improve the product quality of the wafer 20. On the other hand, the reaction gas after reaction above the wafer 20 may also be discharged outwards through the ventilation hole 13.

Further, the cylinder 11 and the supporting block 12 have an integrated structure; and the cylinder 11 and the supporting block 12 are both high-temperature and high-pressure resistant ceramic bodies. In this way, the ceramic body is resistant to high temperatures and high pressures, and does not chemically react with the reaction gas; at the same time, the material is hard, is not easy to damage, and has a long service life. Certainly, the cylinder 11 and the supporting block 12 may also be made of other materials resistant to high temperatures and high pressures and not chemically reacting with the reaction gas, which is not limited herein.

As an alternative, when a reaction temperature in the reaction furnace body 30 is within 100° C. or between 100° C. and 200° C., the wafer support 10 further includes a heating member. The heating member is arranged on the cylinder 11, and the heating member is provided with a heat conducting plate correspondingly fitted to the supporting blocks 12. In this way, the heating member operates synchronously while the reaction gas is introduced above the wafer 20. The heating member transfers heat to the supporting block 12 through the heat conducting plate, and the supporting block 12 transfers the heat to a local part of an edge of the wafer 20. This can increase a reaction speed of the reaction gas at the local part, so as to increase the thickness of the film corresponding to the local part of the edge part of the wafer 20, and thickness uniformity of the edge of the wafer 20 can be improved, thereby improving the product quality of the wafer 20.

Further, the heating member is detachably mounted on the cylinder 11. In this way, when the reaction temperature in the reaction furnace body 30 is above 200° C., the heating member is removed from the cylinder 11 without being mounted on the cylinder 11, so as to avoid the adverse effect of the high-temperature gas in the reaction furnace body 30 on the heating member. In addition, when the heating member has no heating effect on the supporting blocks 12, the heating member can be removed from the cylinder 11.

Further, referring to FIG. 2 to FIG. 4, FIG. 7 and FIG. 8, the supporting block 12 may be in a shape of a square or a triangle, or in other shapes, which is not limited thereto.

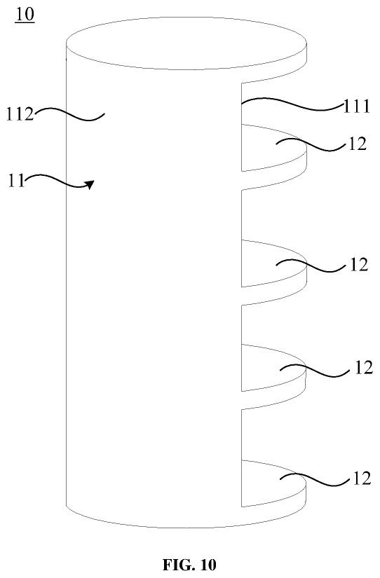

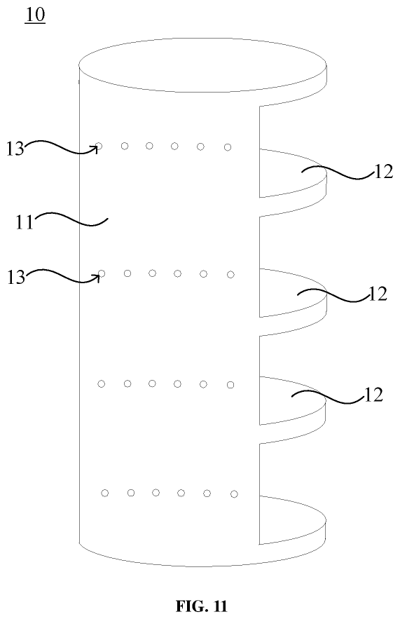

In one embodiment, referring to FIG. 9 to FIG. 12, a wafer support 10 includes a cylinder 11 and supporting blocks 12. The cylinder 11 is an elliptic cylinder 11. A sidewall of the cylinder 11 includes a first wall surface 111 facing a wafer 20 and a second wall surface 112 facing away from the wafer 20. The first wall surface 111 is connected to the second wall surface 112, and the second wall surface 112 is an elliptic cylindrical surface. A number of supporting blocks 12 are provided. The one or more supporting blocks 12 are sequentially spaced apart on the first wall surface 111 from top to bottom. The supporting block 12 is configured to support the wafer 20.

In the wafer support 10, the sidewall of the cylinder 11 includes the first wall surface 111 and the second wall surface 112, the second wall surface 112 is the elliptic cylindrical surface, and the resistance of the sidewall of the cylinder 11 to the reaction gas discharged from the nozzle of the air duct 40 is reduced. In this way, the reaction gas discharged from the nozzle of the air duct 40 can flow uniformly over the entire surface of the wafer 20, the amount of gas on the surface part of the wafer 20 corresponding to the supporting block 12 is basically the same as the amount of gas on other parts of the wafer 20, and then the thickness of the film formed by deposition on the surface part of the wafer 20 corresponding to the supporting block 12 is basically the same as that of the film on other parts of the wafer 20. That is, the uniformity of deposition thicknesses of edge parts of the wafer 20 can be improved, so as to improve the product quality of the wafer 20. In addition, the width of the cylinder 11 is relatively decreased, and in the process of withdrawing the gas after reaction corresponding to the wafer 20 from the furnace body through the suction mechanism 50, the blocking effect of the cylinder 11 is also weakened, and the reaction gas is timely withdrawn from the reaction furnace body 30, so as to avoid as much as possible residence of the reaction gas in the region of the wafer support 10 which may react and produce by-product particles. Moreover, the by-product particles are also easy to be withdrawn from the furnace body by the suction mechanism 50.

Further, referring to FIG. 9 to FIG. 11, a short axis of the elliptic cylinder 11 is b, and the b is not greater than 0.5 cm. In this way, the width of the cylinder 11 is relatively reduced; in other words, the blocking effect on the reaction gas is reduced, which is conducive to the flow of the reaction gas above the surface of the wafer 20.

Specifically, referring to FIG. 9 to FIG. 11, the second wall surface 112 is one part of the elliptic cylindrical surface, and wall surface of the supporting block 12 is the other part of the elliptic cylindrical surface. That is, a top view of the wafer support 10 is a complete ellipse.

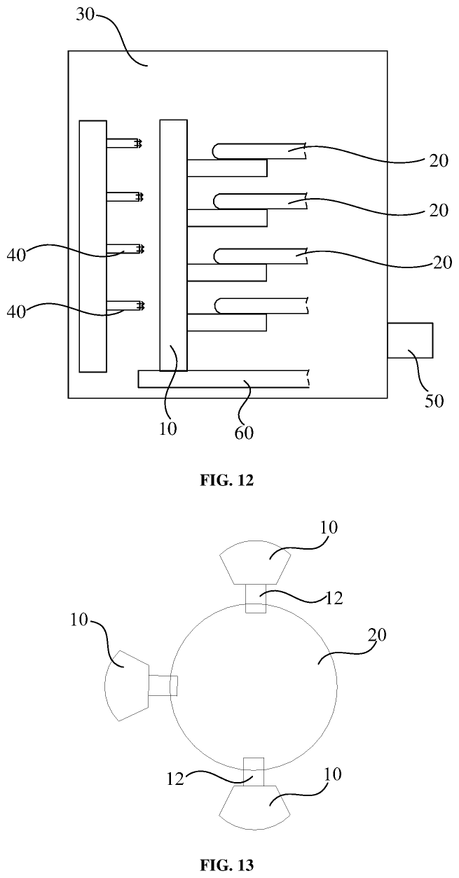

In one embodiment, referring to FIG. 12 to FIG. 13, a wafer processing device includes the wafer support 10 according to any one of the above embodiments, and further includes a reaction furnace body 30, an air duct 40 and a suction mechanism 50. The wafer support 10 is mounted in the reaction furnace body 30, the air duct 40 is configured to introduce reaction gas into the reaction furnace body 30, and the suction mechanism 50 is configured to withdraw the reaction gas in the reaction furnace body 30 from the reaction furnace body 30.

Since the wafer processing device includes the wafer support 10, the technical effect thereof is brought by the wafer support 10 and the beneficial effect is the same as that of the wafer support 10, which is not described in detail herein.

Further, referring to FIG. 12 to FIG. 13, a number of wafer supports 10 are provided. The one or more wafer supports 10 are spaced apart around the wafer 20. One or more supporting blocks 12 of the wafer supports 10 are arranged in one-to-one correspondence. In this way, the wafer 20 is mounted synchronously on the supporting block 12 in the same plane of the one or more wafer supports 10, and the fixation effect of the wafer 20 is relatively stable. Specifically, with two, three or four wafer supports 10, the wafer 20 can be securely mounted. Certainly, the number of the wafer support 10 may also be other values, which is not limited herein.

Further, referring to FIG. 12 to FIG. 13, the wafer processing device further includes a rotary table 60 arranged in the reaction furnace body 30. The cylinder 11 is connected to the rotary table 60. In this way, in the process of introducing the reaction gas into the reaction furnace body 30, the rotary table 60 is synchronously driven to rotate, and the rotary table 60 drives the wafer 20 to rotate during rotation, so that the reaction gas flows more uniformly above the wafer 20, the reaction gas discharged from the nozzle of the air duct 40 can flow uniformly over the entire surface of the wafer 20, the amount of gas on the surface part of the wafer 20 corresponding to the supporting blocks 12 is basically the same as that on other parts of the wafer 20, and then the thickness of the film formed by deposition on the surface part of the wafer 20 corresponding to the supporting block 12 is basically the same as that of the film on other parts of the wafer 20. That is, the uniformity of deposition thicknesses of edge parts of the wafer 20 can be improved, so as to improve the product quality of the wafer 20.

In one embodiment, a wafer processing method is provided, which is a method using the wafer processing device according to any one of the above embodiments for wafer processing.

Since the wafer processing method is a method using the wafer processing device for wafer processing, the technical effect thereof is brought by the wafer processing device and the beneficial effect is the same as that of the wafer processing device, which is not described in detail herein.

Technical features of the above embodiments may be combined randomly. To make descriptions brief, not all possible combinations of the technical features in the embodiments are described. Therefore, as long as there is no contradiction between the combinations of the technical features, they should all be considered as scopes disclosed in the specification.

The above embodiments only describe several implementations of the present invention, which are described specifically and in detail, and therefore cannot be construed as a limitation on the patent scope of the present invention. It should be pointed out that those of ordinary skill in the art may make various changes and improvements without departing from the ideas of the present invention, which shall all fall within the protection scope of the present invention. Therefore, the patent protection scope of the present invention shall be subject to the appended claims.

What is claimed is:

1. A wafer support, comprising:
a cylinder, a sidewall of the cylinder comprising a first wall surface facing a wafer, a second wall surface facing away from the wafer and two third wall surfaces connected to the first wall surface and the second wall surface, the first wall surface being arranged opposite to the second wall surface, the two third wall surfaces being arranged opposite to each other, the two third wall surfaces being arranged at an angle, and a distance between the two third wall surfaces gradually decreasing in a direction close to the first wall surface; and
one or more supporting blocks sequentially spaced apart on the first wall surface from top to bottom, the supporting blocks being configured to support the wafer.

2. The wafer support according to claim 1, wherein a distance between the sides of the two third wall surfaces close to the second wall surface is W, where W is not greater than 1 cm.

3. The wafer support according to claim 1, wherein the first wall surface is a plane, the third wall surface is also a plane, inclined relative to the first wall surface, and an angle between the third wall surface and the first wall surface is a, where a is 20° to 50°.

4. The wafer support according to claim 3, wherein a is 30° to 40°.

5. The wafer support according to claim 1, wherein the first wall surface is an arc-shaped surface, the second wall surface is an arc-shaped surface, and the third wall surface is a plane.

6. The wafer support according to claim 1, wherein the cylinder is further provided with one or more ventilation holes, the ventilation holes are arranged corresponding to the supporting blocks, and the ventilation hole extends from the first wall surface to the second wall surface.

7. The wafer support according to claim 1, wherein the cylinder and the supporting blocks have an integrated structure, and the cylinder and the supporting blocks are both high-temperature and high-pressure resistant ceramic bodies.

8. The wafer support according to claim 1, further comprising a heating member arranged on the cylinder, the heating member being provided with a heat conducting plate correspondingly fitted to the supporting blocks.

9. The wafer support according to claim 8, wherein the heating member is detachably mounted on the cylinder.

10. A wafer support, comprising:
a cylinder that is an elliptic cylinder, a sidewall of the cylinder comprising a first wall surface facing a wafer and a second wall surface facing away from the wafer, the first wall surface being connected to the second wall surface, and the second wall surface being an elliptic cylindrical surface; and
one or more supporting blocks sequentially spaced apart on the first wall surface from top to bottom, the supporting blocks being configured to support the wafer.

11. The wafer support according to claim 10, further comprising a heating member arranged on the cylinder, the heating member being provided with a heat conducting plate correspondingly fitted to the supporting blocks.

12. The wafer support according to claim 11, wherein a short axis of the elliptic cylinder is b, and the b is not greater than 0.5 cm.

13. A wafer processing device, comprising the wafer support according to claim 1, one or more wafer supports being provided, the one or more wafer supports being spaced apart around the wafer, and the supporting blocks of the one or more wafer supports being arranged in one-to-one correspondence.

14. The wafer processing device according to claim 13, further comprising a reaction furnace body, an air duct and a suction mechanism;
wherein the wafer support is mounted in the reaction furnace body, the air duct is configured to introduce reaction gas into the reaction furnace body, and the suction mechanism is configured to withdraw the reaction gas in the reaction furnace body from the reaction furnace body.

15. The wafer processing device according to claim 14, further comprising a rotary table arranged in the reaction furnace body, the cylinder being connected to the rotary table.

16. A wafer processing method, using the wafer processing device according to claim 13 for wafer processing.

17. A wafer processing device, comprising the wafer support according to claim 10, one or more wafer supports being provided, the one or more wafer supports being spaced apart around the wafer, and the supporting blocks of the one or more wafer supports being arranged in one-to-one correspondence.

18. The wafer processing device according to claim 17, further comprising a reaction furnace body, an air duct and a suction mechanism;
wherein the wafer support is mounted in the reaction furnace body, the air duct is configured to introduce reaction gas into the reaction furnace body, and the suction mechanism is configured to withdraw the reaction gas in the reaction furnace body from the reaction furnace body.

19. The wafer processing device according to claim 18, further comprising a rotary table arranged in the reaction furnace body, the cylinder being connected to the rotary table.

20. A wafer processing method, using the wafer processing device according to claim 17 for wafer processing.
